(19) United States
(12) Patent Application Publication
(10) Pub. No.: US 2006/0017058 A1
(43) Pub. Date: Jan. 26, 2006

(54) Construction of LED circuit board

(75) Inventor: Ming-Shun Lee, Taipei (TW)

Correspondence Address: TROXELL LAW OFFICE PLLC, SUITE 1404, 5205 LEESBURG PIKE, FALLS CHURCH, VA, 22041, US

(73) Assignee: Taiwan Oasis Technology Co., Ltd.

(21) Appl. No.: 10/896,033

(22) Filed: Jul. 22, 2004

(51) Int. Cl. H01L 33/00

(52) U.S. Cl. 257/99

(57) ABSTRACT

A LED circuit board construction having the circuit board provided with a pit carrier on a baseboard; multiple conduction circuits of different polarities being provided on the peripheral of the carrier; one end of the conduction circuit facing the carrier related to a chip conductor maintaining a fixed spacing from the carrier; the other end of the conduction circuit related to a service assembly end extending to the edge of the circuit board; a chip being disposed in the carrier; and a golden plated wire connecting an electrode layer of the chip and the chip conductor of the conduction circuit.

### BACKGROUND OF THE INVENTION

(a) Field of the Invention

The present invention is related to an improved construction of a flat LED circuit board, and more particularly, to a simple construction allowing the completion of given number of flat LED on a molding plate in a given size.

(b) Description of the Prior Art

Production cost of light emitting diode (LED) has been significantly reduced thanks to continuous improvement in LED process technology. Furthermore, the LED capable of emitting a given light color by directly incorporating the wavelength of light source from a chip and that of a fluorescence material is gradually taking over the applications of the conventional bulbs in Christmas decoration light strings, flashlight and traffic signs, and is extremely fast expanding its market territory.

While enjoying its expanded applications, the LED is evolving either in its construction or appearance. Other than the most common form of having an electricity pin extended from a light emission end, the LED may be directly built on a circuit board. Therefore, the improved construction disclosed in the present invention essentially involves a simple construction of a circuit board in a given size provided with a given number of flat LED to help control of costs of materials and control of materials and quantity similar to that for LED device.

### SUMMARY OF THE INVENTION

The primary purpose of the present invention is to provide a construction of LED circuit board essentially comprised of a pit carrier on a baseboard and multiple conduction circuits of different polarities on the peripheral of the carrier. One end facing toward the carrier of each conduction circuit is related to a chip conductor maintaining a fixed spacing with the carrier while the other end of the conduction circuit extends to the edge of the circuit board to become a service assembly end for the use of the LED. A chip is plated to the carrier and a golden plated wire connects an electrode layer of the chip and the chip conductor of each conduction circuit for the configuration of an LED circuit board.

Furthermore, in the molding process of the circuit board of the present invention, each LED baseboard is arranged on a molding board at a given spacing from another LED baseboard to allow the mass production of the LED baseboard in the automated process. The present invention also facilitates the automated process in the subsequent process for the production of the LED. Accordingly, the present invention by allowing the completion of a given number of flat LED on the molding board in a given size helps the material/quantity control similar to that for the LED device.

### BRIEF DESCRIPTION OF THE DRAWINGS

FIG. 1 is an upward view of a layout of a first preferred embodiment of the present invention.

FIG. 2 is a sectional view of a local part of the LED of the present invention.

FIG. 3 is an upward view of a layout of a second preferred embodiment of the present invention.

FIG. 4 is a layout of a molding board of the circuit board of the present invention.

FIG. 5 is an upward view of a layout of a third preferred embodiment of the present invention.

### DETAILED DESCRIPTION OF THE PREFERRED EMBODIMENTS

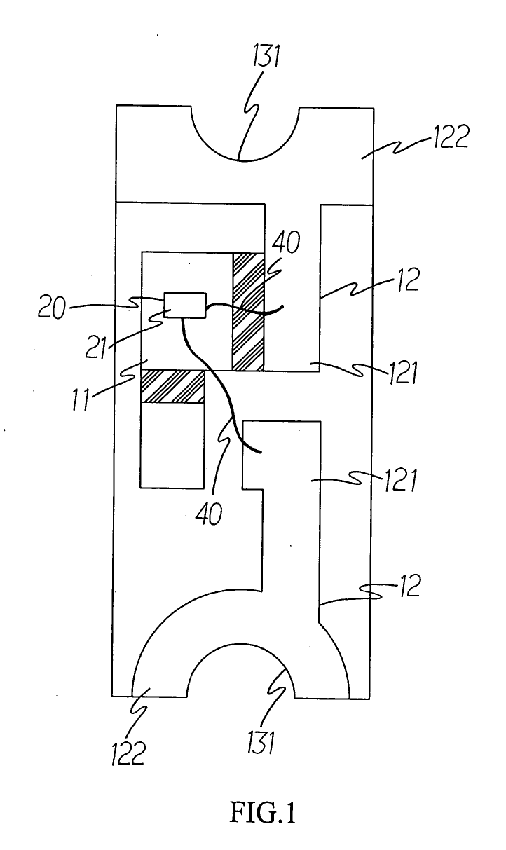

Referring to FIG. 1, a basic construction of a circuit board of the present invention is comprised of a pit carrier 11 provided on a baseboard 10 and multiple conduction circuit 12 of different polarities disposed on the peripheral of the carrier 11. Each conduction circuit 12 relates to a cooper foil printed on the baseboard 10. Once end facing the carrier 11 of each conduction circuit 12 relates to a chip conductor 121 keeping a fixed spacing with the carrier, and the other end of the conduction circuit 12 extends to the edge of the baseboard 10 to become a service assembly end 122 to function as a soldering end for related circuit when the baseboard 10 is used as an LED.

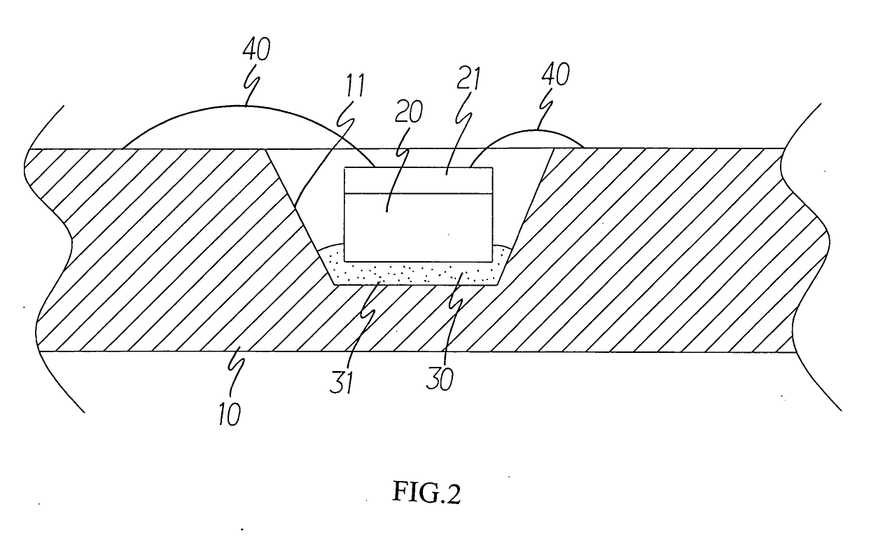

Accordingly, a chip 20 is planted in the carrier 11 on the baseboard 10 as illustrated in FIGS. 1 and 2. Wherein, the chip 20 is fixed to the bottom of the carrier 11 with an adhesive 30 mixed with a fluorescent material 31; a golden plated wire 40 connects an electrode layer 21 of the chip and the chip conductor 121 of each conduction circuit 12; and a transparent capping layer 50 made of a transparent insulation glue covers up the surface of the chip to become an integral flat LED.

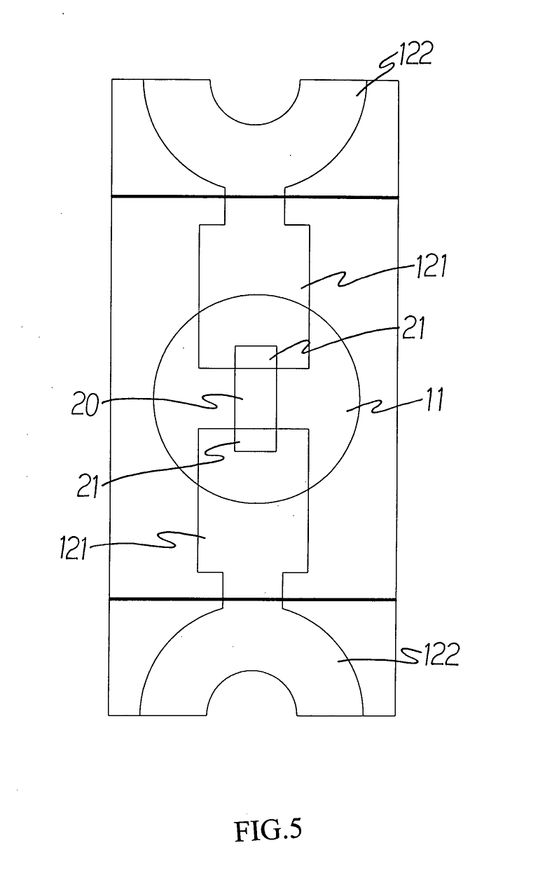

The circuit of the chip conductor 121 and the service assembly end 122 of each conduction circuit 12 can be arranged on the baseboard 10 as illustrated in FIG. 5. Wherein, one end of the chip conductor 121 is connected to the service assembly end 122, and the other end is laid on one side of the carrier 11. Therefore, when the chip 20 is fixed to the bottom of the carrier 11 using the adhesive 30 mixed with the fluorescent material 31, the chip is connected to the chip conductor 121 of each conduction circuit without relying upon the golden plated wire 40.

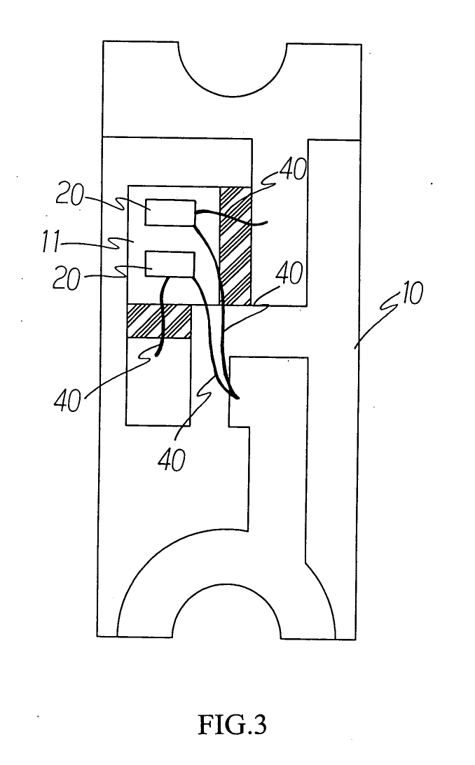

Each flat LED, as illustrated in FIG. 3, may be provided in the same carrier 11 multiple chips to increase the luminance of the LED.

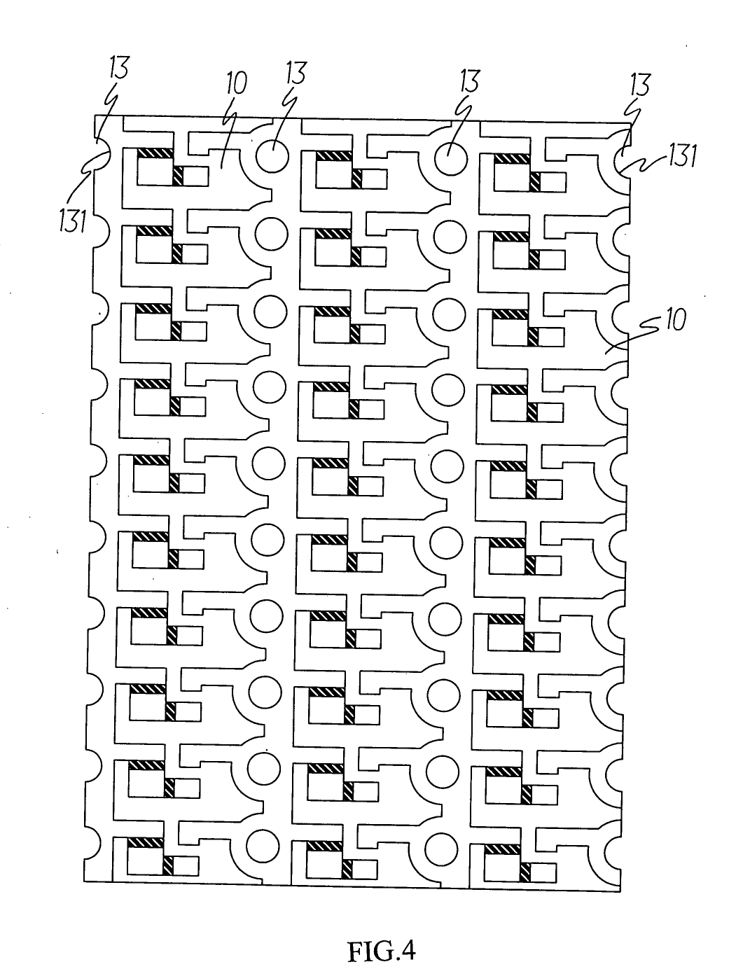

Now referred in to FIG. 4, each LED baseboard 10 may be arranged on a molding board at a given spacing from another LED baseboard 10 to allow massive production in an automated process. The present invention also facilitates the automated process in the subsequent manufacturing of LED by completing a given number of flat LED on the molding board in given size so to help the material/quantity control similar to that for LED device.

When the construction of the circuit board of the present invention allows multiple LED baseboards 10 arranged on the molding board at a given spacing from one another for the mass production, the molding board is provided with a positioning hole between any two abutted baseboards 10 to facilitate the positioning in the manufacturing process. The positioning hole 12 may be disposed at the service 3 assembly end of each conduction circuit 12. According, upon feeding the individual baseboard as illustrated in FIGS. 1 and 4, the positioning hole 13 serves a dividing point of the feeding for a concave 13 to be produced at the edge of the service assembly end 122 of each conduction circuit for the baseboard 10 fed to facilitate the attachment of the solder (soldering tin) to help the assembly between the LED and related circuits.

The present invention provides an improved construction of a flat LED circuit board, therefore, this application for a utility patent is duly filed accordingly. However, it is to be noted that that those preferred embodiments disclosed in the specification and the accompanying drawings are in no way limiting the present invention. Therefore, any construction, installation, or characteristics that is same or similar to that of the present invention should fall within the scope of the purposes and claims of the present invention.

I claim:

1. A LED circuit board construction having the circuit board provided with a pit carrier on a baseboard; multiple conduction circuits of different polarities being provided on the peripheral of the carrier; one end of the conduction circuit facing the carrier related to a chip conductor maintaining a fixed spacing from the carrier; the other end of the conduction circuit related to a service assembly end extending to the edge of the circuit board; a chip being disposed in the carrier; and a golden plated wire connecting an electrode layer of the chip and the chip conductor of the conduction circuit.

2. The LED circuit board construction of claim 1, wherein, the conduction circuit relates to a copper foil printed on the baseboard of the circuit board.

3. The LED circuit board construction of claim 1, wherein, a concave is disposed on the edge of the service assembly end of the conduction circuit.

4. A LED circuit board construction having on a baseboard disposed with a pit carrier; multiple conduction circuits of different polarities being provided on the peripheral of the carrier; one end of the conduction circuit facing the carrier related to a chip conductor; the chip conductor being arranged on one side in the carrier; the other end of the conduction circuit related to a service assembly end of the LED extending to the edge of the circuit board; chip being disposed in the carrier; the chip conductor in the carrier connecting an electrode layer of the chip and the conduction circuit.
